(19) United States
(12) Patent Application Publication
(10) Pub. No.: US 2026/0313924 A1
(43) Pub. Date: Oct. 8, 2026

(54) CONCENTRIC DTC BUMPS FOR HIGH DENSITY PACKAGE DECAP SOLUTION

(71) Applicant: QUALCOMM Incorporated, San Diego, CA (US)

(72) Inventors: Aniket PATIL, San Diego, CA (US); Yujen CHEN, Taichung (TW); Yangyang SUN, San Diego, CA (US)

(21) Appl. No.: 19/173,559

(22) Filed: Apr. 8, 2025

(51) Int. Cl. H10D 1/68; H10D 1/00; H10D 80/20; H10W 44/00; H10W 70/65; H10W 90/00

(52) U.S. Cl. CPC H10D 1/716; H10D 1/042; H10D 1/043; H10D 80/215; H10W 44/601; H10W 70/65; H10W 90/00; H10W 90/701

(57) ABSTRACT

Disclosed are deep trench capacitors (DTC), also referred to as multi-terminal caps. In conventional DTCs, a plurality of conductive bumps are formed on a base, in which alternating bumps are coupled to power and ground. It is proposed to increase the increase the bump density by providing one or more concentric bump structures in which at least one bump structure includes an inner bump and an outer bump surrounding the inner bump with an insulator in between. The inner bump may be coupled to a first voltage (e.g., power) and the outer bump may be coupled to a second voltage (e.g., ground).

### BACKGROUND OF THE DISCLOSURE

### 1. Field of the Disclosure

This disclosure relates generally to semiconductor packages or modules, and more specifically, but not exclusively, to concentric deep trench capacitor (DTC) bumps for high density package decap solutions and fabrication techniques thereof.

### 2 . Description of the Related Art

Integrated circuit (IC) technology has achieved great strides in advancing computing power through miniaturization of active components. In conventional deep trench capacitor (DTC), conductive bumps are formed to carry power and ground voltages. It would be desirable increase bump count or bump density so that power distribution network performance may be improved.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary deep trench capacitor (DTC) is disclosed. The DTC may comprise a base. The DTC may also comprise one or more concentric bump structures on the base. At least one concentric bump structure may comprise an inner bump, an insulator surrounding the inner bump, and an outer bump surrounding the insulator. The inner bump and the outer bump may be conductive.

A method of fabricating a semiconductor package is disclosed. The method may comprise forming a base. The method may also comprise forming one or more concentric bump structures on the base. At least one concentric bump structure may comprise an inner bump, an insulator surrounding the inner bump, and an outer bump surrounding the insulator. The inner bump and the outer bump may be conductive.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a top view of a conventional deep trench capacitor.

FIG. 2A illustrates a top view of a deep trench capacitor in accordance with one or more aspects of the disclosure.

FIG. 2B illustrates a detailed view of a concentric bump structure of a deep trench capacitor in accordance with one or more aspects of the disclosure.

FIG. 2C illustrates a sectional view of a concentric bump structure and a base of a deep trench capacitor in accordance with one or more aspects of the disclosure.

FIG. 2D illustrates a top view of a concentric bump structure and a base of a deep trench capacitor in accordance with one or more aspects of the disclosure.

FIGS. 3A – 11A and 3B – 11B illustrate stages of a method of fabricating a deep trench capacitor in accordance with one or more aspects of the disclosure.

FIG. 12 illustrates a sectional view of a semiconductor package that includes one or more deep trench capacitors in accordance with one or more aspects of the disclosure.

FIGS. 13A – 13K illustrate stages of method of fabricating a semiconductor package that includes one or more deep trench capacitors in accordance with one or more aspects of the disclosure.

FIGS. 14 – 16 illustrate flow charts of example methods of manufacturing a deep trench capacitor in accordance with at one or more aspects of the disclosure.

FIG. 17 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are deep trench capacitors (DTC) and methods for fabricating the same. In an aspect, the DTC may comprise a base. The DTC may also comprise one or more concentric bump structures on the base. At least one concentric bump structure may comprise an inner bump, an insulator surrounding the inner bump, and an outer bump surrounding the insulator. The inner bump and the outer bump may be conductive. The proposed DTC increases bump density, which can improve power distribution network (PDN) performance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms "a," "an," and "the" are intended to include the plural forms as well, unless the context clearly indicates otherwise. It will be further understood that the terms "comprises," "comprising," "includes," and/or "including," when used herein, specify the presence of stated features, integers, steps, operations, elements, and/or components, but do not preclude the presence or addition of one or more other features, integers, steps, operations, elements, components, and/or groups thereof.

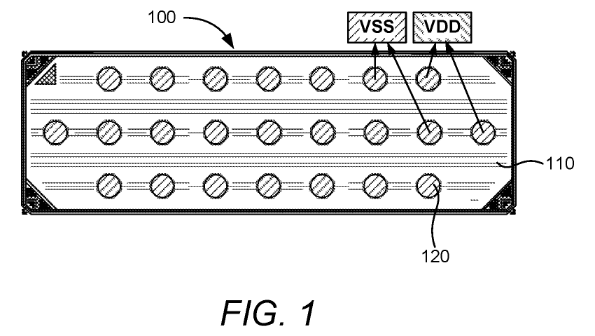

FIG. 1 illustrates a top view of a conventional deep trench capacitor (DTC) 100 that include a base silicon (Si) 110 and a plurality of conductive bumps 120. In the conventional design, power and ground are carried on alternating bumps. However, as indicated above, it would be desirable increase bump count or bump density so that power distribution network (PDN) performance may be improved.

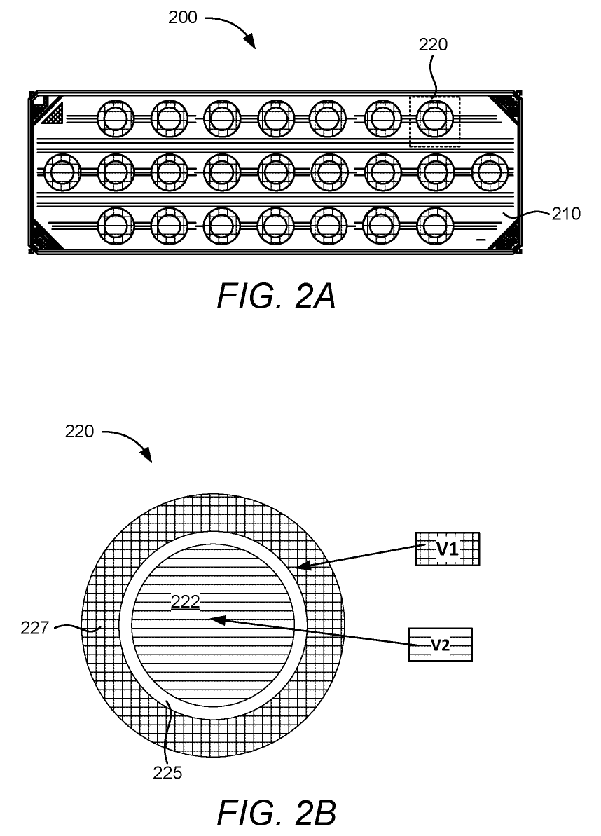

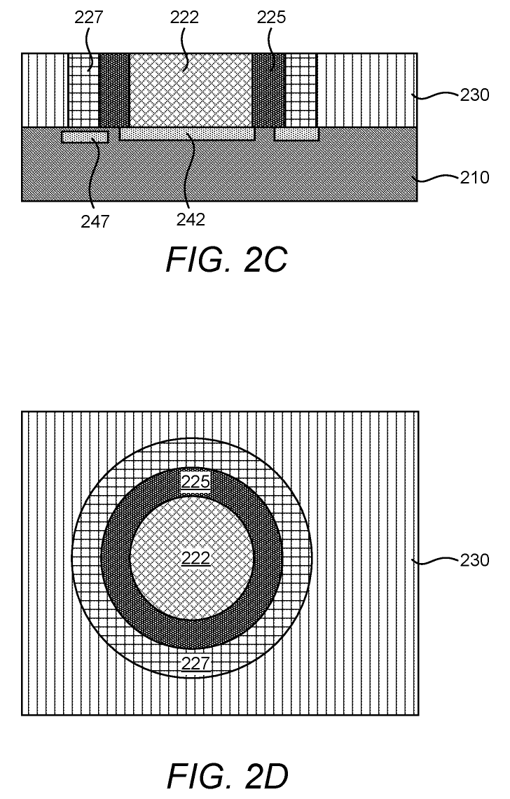

FIG. 2A illustrates a top view of a DTC 200 in accordance with one or more aspects of the disclosure. The DTC 200 may comprise a base 210 and one or more concentric bump structures 220 on the base 210. In an aspect, the base 210 may be formed from silicon (Si).

FIG. 2B illustrates a detailed view of one of the concentric bump structures 220. As seen, the concentric bump structure 220 may comprise an inner bump 222, an insulator 225, and an outer bump 227. The insulator 225 may surround the inner bump 222. The outer bump 227 may surround the insulator 225. In an aspect, the insulator 225 may be formed from a polyimide (PI). Physically, a diameter of the inner bump 222 may range between 30µm and 50µm. Alternatively, or in addition thereto, a thickness of the insulator 225 may range between 5µm and 10µm. Also, alternatively or in addition thereto, an outer diameter of the outer bump 227 may range between 65µm and 95µm.

Both the inner bump 222 and the outer bump 227 may be conductive. In an aspect, the inner bump 222 and the outer bump 227 may be formed from conductive metals, such as copper (Cu). The outer bump 227 may be configured to be coupled with one of a first voltage and a second voltage. For example, the first voltage may be power (e.g., Vdd) and second voltage may be ground (e.g., Vss). The inner bump 222 may be configured to be coupled with the other of the first voltage and the second voltage.

One, some or all of the concentric bump structures 220 may be configured as illustrated in FIG. 2B. Also, the first and second voltages may be same or different for the concentric bump structures 220. That is, the first voltage applied to the outer bump 227 of one concentric bump structure 220 may be same or different from the first voltage applied to the outer bump 227 of another concentric bump structure 220. Since two bumps may be incorporated in one concentric bump structure 220, the overall bump count or bump density may be increased between 1.5 and 1.7 times relative to the conventional DTC, such as the DTC 100 of FIG. 1. This can serve to reduce effective series inductance (ESL) and/or effective series resistance (ESR). As a result, performance of the power distribution network (PDN) may be improved.

FIGS. 2C and 2D illustrates sectional and top views of a more completed DTC 200 in accordance with one or more aspects of the disclosure. As seen, within the base 210, the DTC 200 may also comprise one or more inner pads 242 and one or more outer pads 247. The one or more inner pads 242 may correspond to the one or more concentric bump structure 220. Each inner pad 242 may be in contact with – or more generally, electrically coupled with – a lower surface of the inner bump 222 of the corresponding concentric bump structure 220. Similarly, the one or more outer pads 247 may also correspond to the one or more concentric bump structure 220. Each outer pad 247 may be in contact with – or more generally, electrically coupled with – a lower surface of the outer bump 227 of the corresponding concentric bump structure 220. In an aspect, the inner pad 242 and/or the outer pad 247 may be formed from a second metal layer M2.

The DTC 200 may further comprise a cap mold 230 on the base 210. The cap mold 230 may encapsulate outer sides of the outer bumps 227 of the one or more concentric bump structures 220.

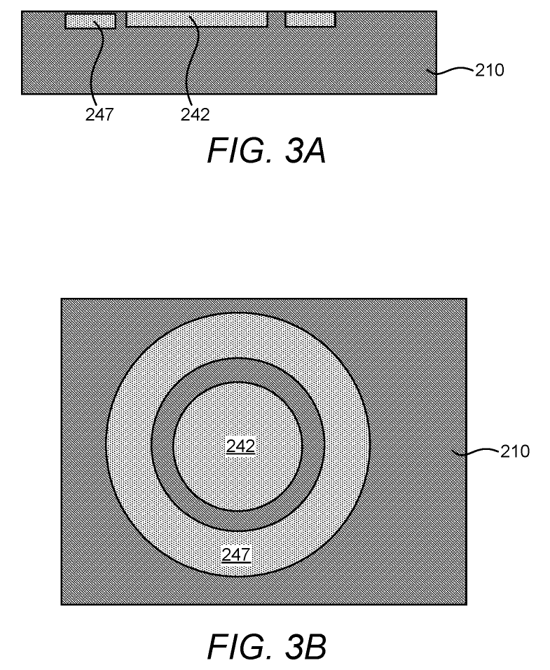

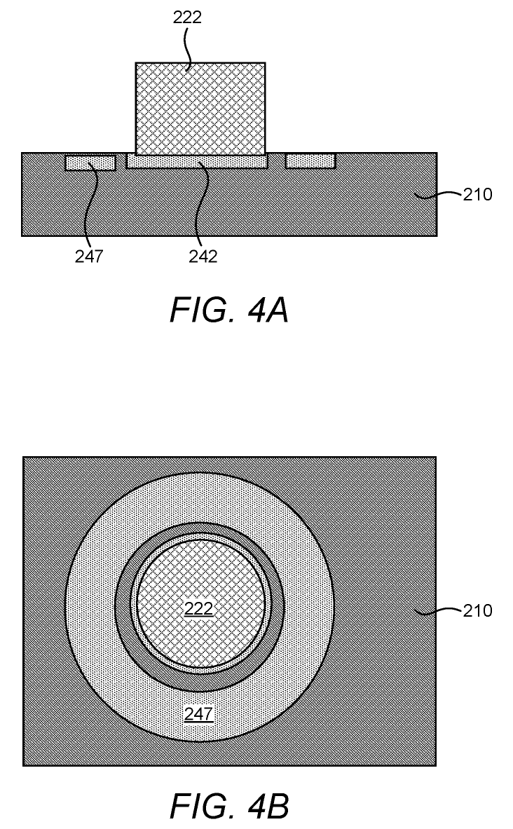

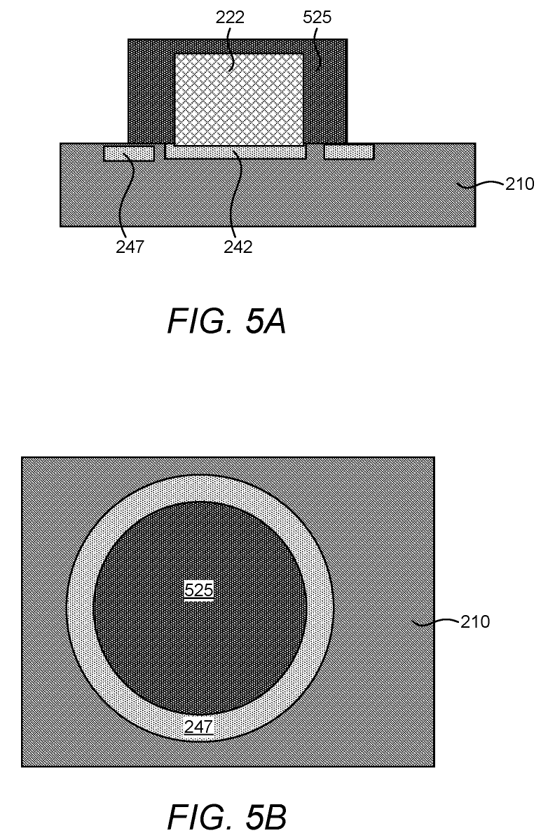

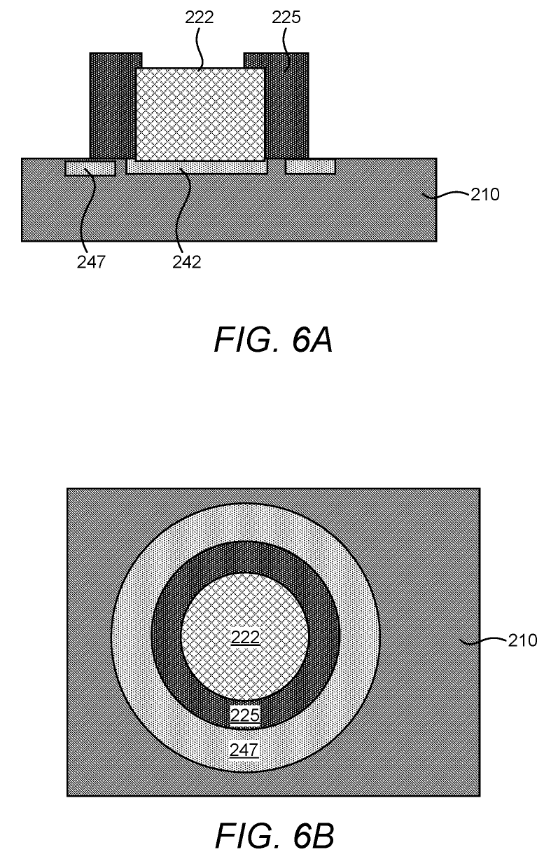

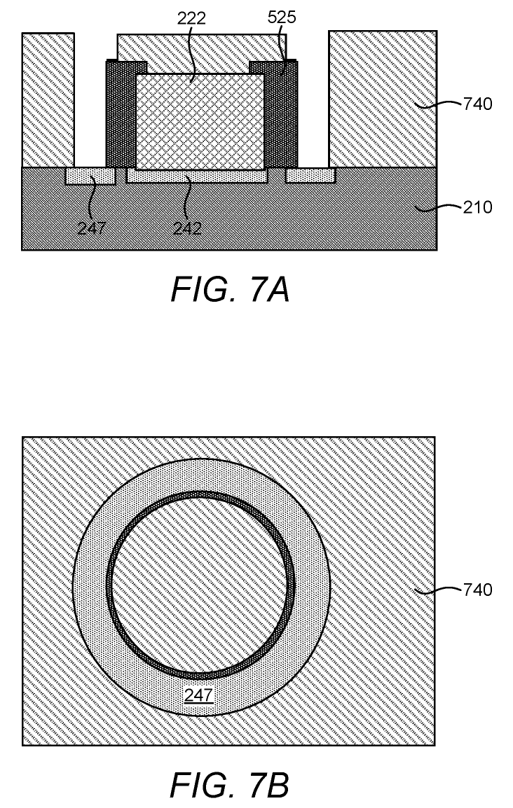

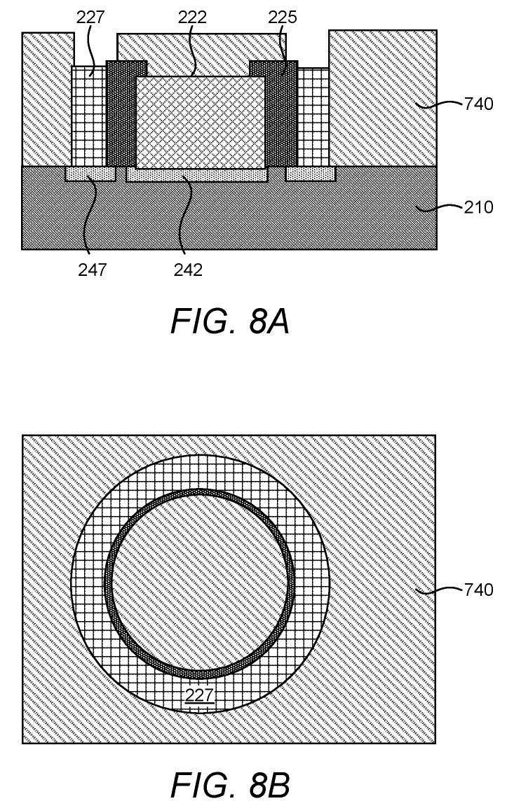

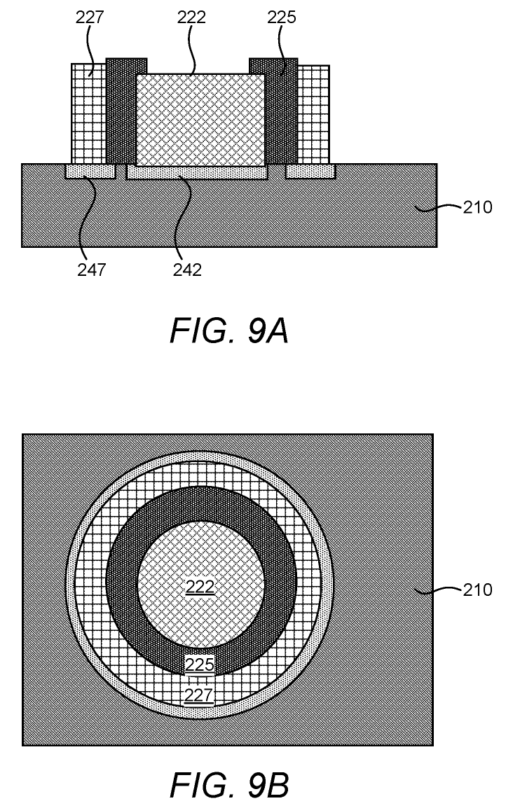

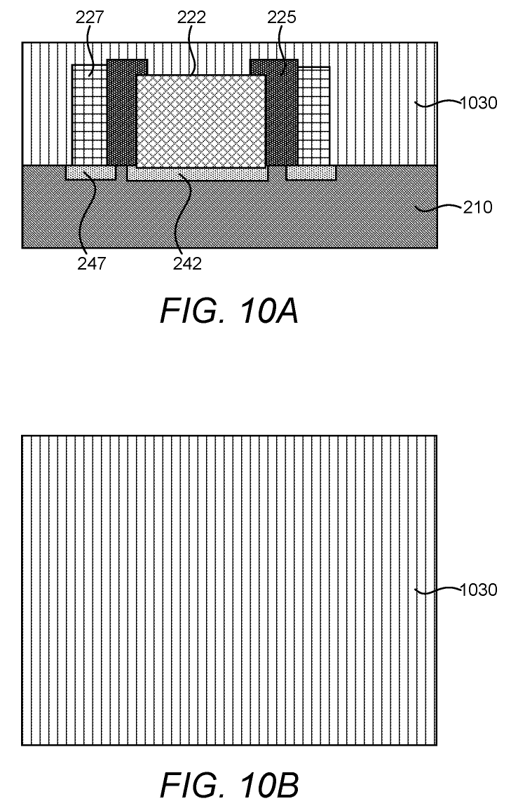

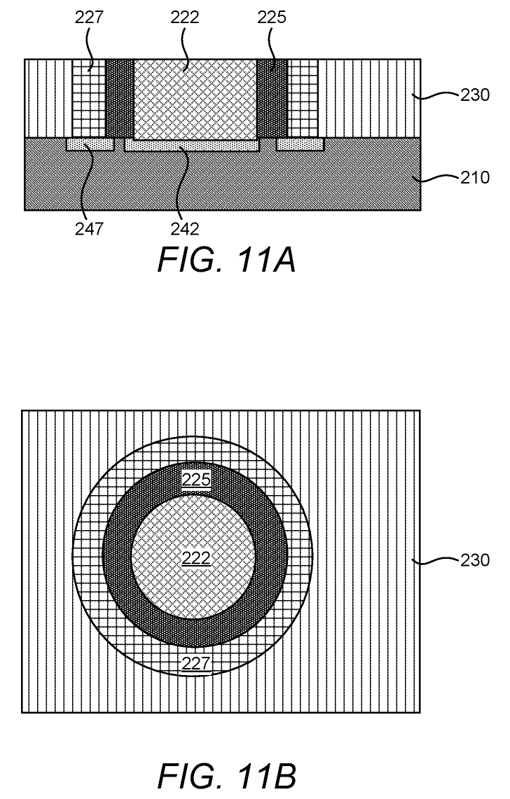

FIGS. 3A – 11B illustrate stages of a method of fabricating a deep trench capacitor in accordance with one or more aspects of the disclosure. FIGS. 3A – 11A illustrate sectional views and FIGS. 3B – 11B illustrate top views.

FIGS. 3A and 3B illustrate a stage in which an incoming wafer with concentric pads are provided. That is, FIGS. 3A and 3B illustrate a stage in which the base 210 is provided. The inner pads 242 and the outer pads 247 may be within the base 210.

FIGS. 4A and 4B illustrate a stage in which the inner bump 222 is formed on the inner pad 242.

FIGS. 5A and 5B illustrate a stage in which an insulator material 525 (e.g., polyimide) may be deposited on the inner bump 222 and on the base 210. The insulator material 525 may encapsulate side and upper surfaces of the inner bump 222.

FIGS. 6A and 6B illustrate a stage in which the insulator material 525 may be patterned to expose an upper surface of the inner bump 222. The patterned insulator material 525 may form the insulator 225.

FIGS. 7A and 7B illustrate a stage in which a mask, such as photoresist (PR) 740, may be deposited on the base 210, on the inner bump 222, and on the insulator 225. The deposited PR 740 may be patterned to expose an upper surface of the outer pad 247.

FIGS. 8A and 8B illustrate a stage in which a conductive metal (e.g., Cu) may be plated on the exposed upper surface of the outer pad 247 to form the outer bump 227.

FIGS. 9A and 9B illustrate a stage in which the mask, e.g., the PR 740, may be removed.

FIGS. 10A and 10B illustrate a stage in which a mold material 1030 may be deposited on the base 210, on the outer bump 227, on the insulator 225, and on the inner bump 222.

FIGS. 11A and 11B illustrate a stage in which the mold material 1030 may be planarized to form the cap mold 230.

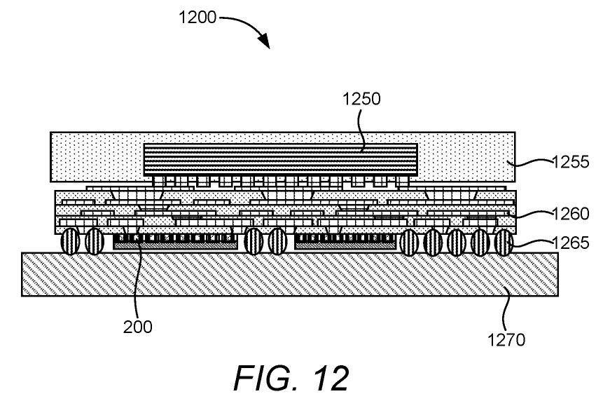

FIG. 12 illustrates a sectional view of a semiconductor package 1200 that includes one or more DTCs 200 in accordance with one or more aspects of the disclosure. The semiconductor package 1200 may comprise a redistribution layer (RDL) 1260. The RDL 1260 may include one or more metal layers configured to distribute signals and/or carry power and ground voltages. A die 1250 may be provided on an upper surface of the RDL 1260. The die 1250 may be any type of die such as memory die, system-on-chip (SoC), passive component (e.g., capacitor, inductor, resistor, etc.) and so on. A die mold 1255 may be formed on the upper surface of the RDL 1260. The die mold 1255 may encapsulate side and upper surfaces of the die 1250.

The semiconductor package 1200 may also comprise one or more DTCs 200 on a lower surface of the RDL 1260. In an aspect, at least one DTC 200 may be electrically coupled to the die 1250 through the RDL 1260.

The semiconductor package 1200 may further comprise a printed circuit board (PCB) 1270 below the RDL 1260. A plurality interconnects 1265 may be formed in between the RDL 1260 and the PCB 1270. The PCB 1270 may be electrically coupled with the die 1250 through one or more of the interconnects 1265 and the RDL 1260. Alternatively, or in addition thereto, the PCB 1270 may be electrically coupled with at least one of the DTCs 200 through one or more of the interconnects 1265 and the RDL 1260.

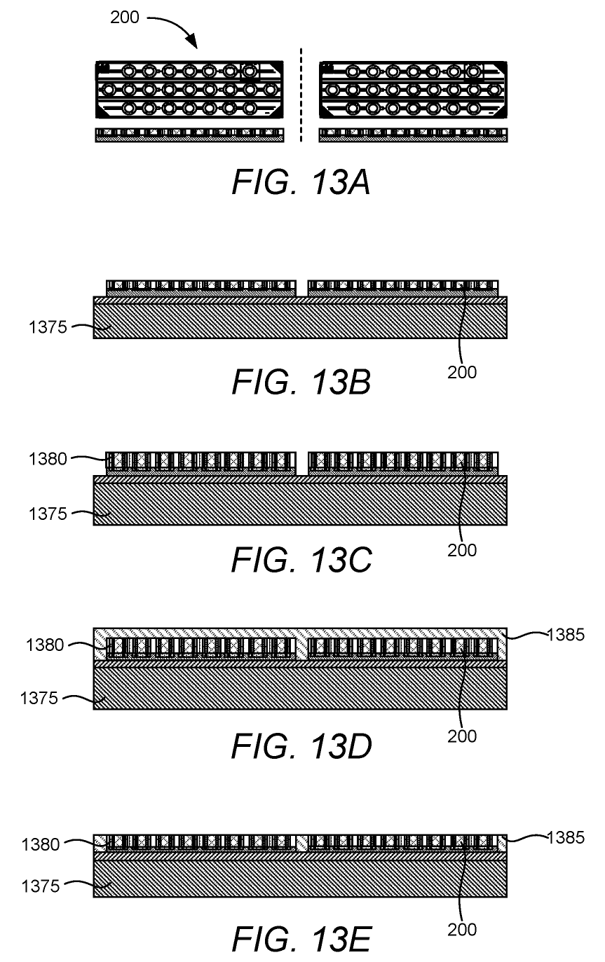

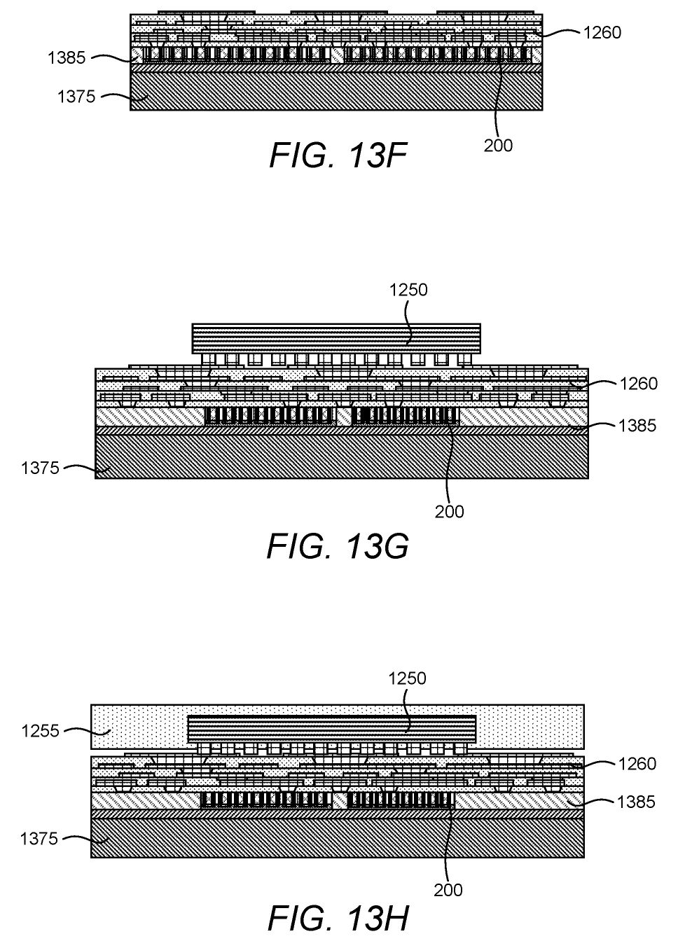

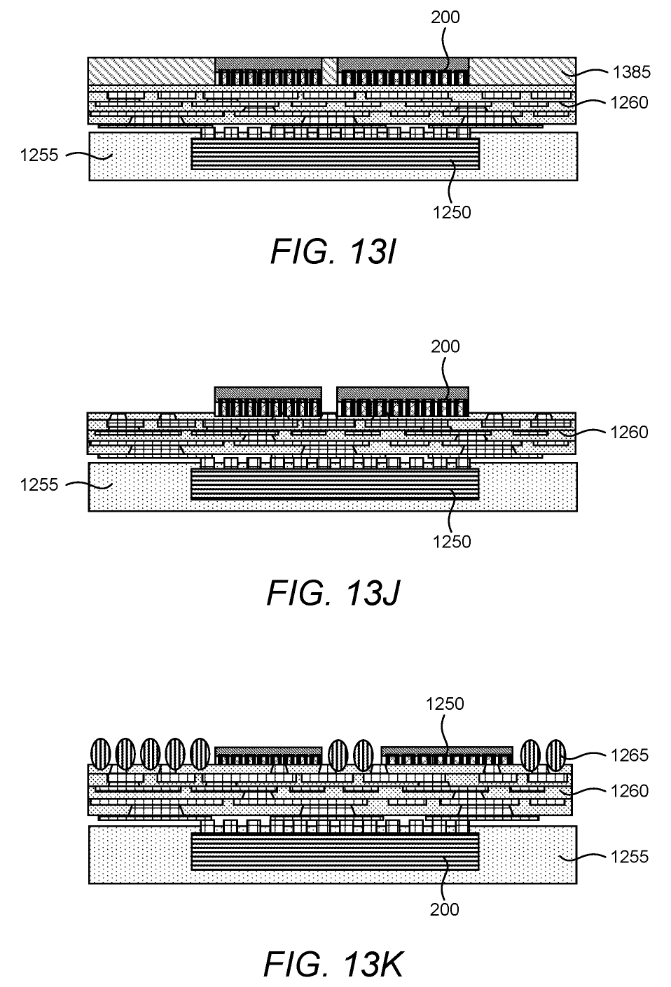

FIGS. 13A – 13K illustrate stages of method of fabricating a semiconductor package that includes a deep trench capacitor, such as the semiconductor package 1200, in accordance with one or more aspects of the disclosure.

FIG. 13A illustrates a stage in which the DTC 200s are provided. Any number of DTC 200 may be provided. But in FIGS. 13A – 13J, it is assumed that two DTCs 200 are provided. In FIG. 13A, both top and sectional views are shown. But for FIGS. 13B – 13K, only sectional views are shown. The DTCs 200 may be assumed to have been singulated.

FIG. 13B illustrates a stage in which the DTCs 200 are provided on a carrier 1375. The carrier 1375 may comprise an adhesive.

FIG. 13C illustrates a stage in which metal (e.g., Cu) plating 1380 is performed for the DTC bumps.

FIG. 13D illustrates a stage in which a temporary adhesive film 1385 is formed. The temporary adhesive film 1385 may serve to protect the landside components (LSC) of the DTC 200.

FIG. 13E illustrates a stage in which temporary adhesive film 1385 may be planrized (e.g., backgrinded) to expose the DTC pads.

FIG. 13F illustrates a stage in which RDL process is performed to form the RDL 1260.

FIG. 13G illustrates a stage in which the die 1250 may be attached to the RDL 1260. For example, die bumps may be attached to the metals of the RDL 1260.

FIG. 13H illustrates a stage in which the die mold 1255 may be formed.

FIG. 13I illustrates a stage in which the carrier 1375 is removed and the remaining assembly is flipped.

FIG. 13J illustrates a stage in which the temporary adhesive film 1385 is removed.

FIG. 13K illustrates a stage in which the interconnects 1265 (e.g., solder balls) are formed. Solder reflow may also be performed.

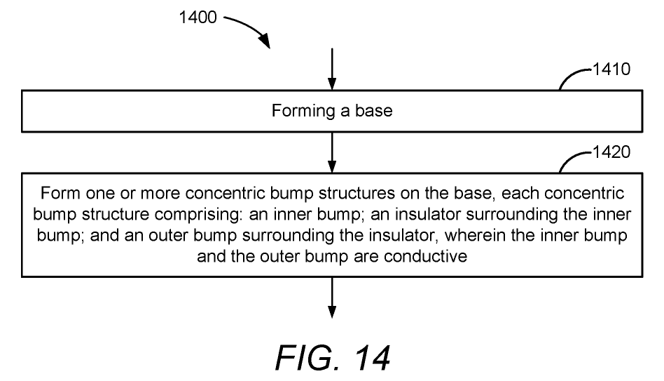

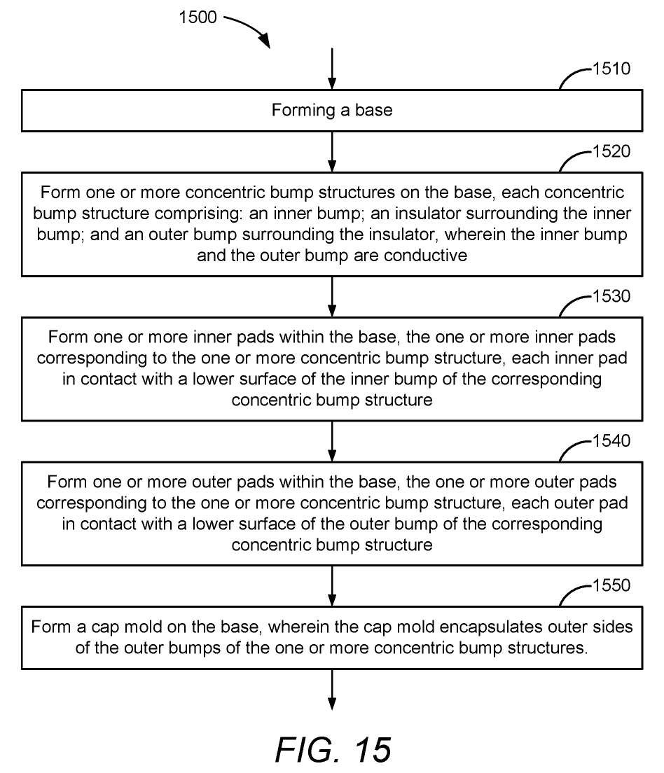

FIG. 14 illustrates a flow chart of an example method 1400 of fabricating a deep trench capacitor (DTC), such as the DTC 200, in accordance with one or more aspects of the disclosure.

In block 1410, a base 210 may be formed.

In block 1420, one or more concentric bump structures 220 may be formed on the base 210. One, some or all of the concentric bump structures 220 may comprise an inner bump 222, an insulator 225 surrounding the inner bump 222, and an outer bump 227 surrounding the insulator 225. The inner bump 222 and the outer bump 227 may be conductive.

FIG. 15 illustrates a flow chart of another example method 1500 of fabricating a deep trench capacitor (DTC), such as the DTC 200, in accordance with one or more aspects of the disclosure. FIG. 15 may be viewed as being more detailed version.

Block 1510 may be similar to block 1410. That is, in block 1510, a base 210 may be formed.

Block 1520 may be similar to block 1420. That is, in block 1520, one or more concentric bump structures 220 may be formed on the base 210. One, some or all of the concentric bump structures 220 may comprise an inner bump 222, an insulator 225 surrounding the inner bump 222, and an outer bump 227 surrounding the insulator 225. The inner bump 222 and the outer bump 227 may be conductive.

In block 1530, one or more inner pads 242 may be formed within the base 210. The one or more inner pads 242 may correspond to the one or more concentric bump structure 220. Each inner pad 242 in contact with a lower surface of the inner bump 222 of the corresponding concentric bump structure 220. More generally, each inner pad 242 may be electrically coupled with the inner bump 222 of the corresponding concentric bump structure 220.

In block 1540, one or more outer pads 247 may be formed within the base 210. The one or more outer pads 247 may correspond to the one or more concentric bump structure 220. Each outer pad 247 may be in contact with a lower surface of the outer bump 227 of the corresponding concentric bump structure 220. More generally, each outer pad 247 may be electrically coupled with the outer bump 227 of the corresponding concentric bump structure 220.

In block 1550, a cap mold 230 may be formed on the base 210. The cap mold 230 may encapsulates outer sides of the outer bumps 227 of the one or more concentric bump structures 220.

FIG. 16 illustrates an example process to implement block 1520 of forming the one or more bump structures and block 1550 of forming the cap mold 230.

In block 1610, the inner bump 222 may be formed on the inner pad 242.

In block 1620, an insulator material 525 may be deposited on the inner bump 222 and on the base 210. The insulator material 525 may encapsulate side and upper surfaces of the inner bump 222.

In block 1630, the insulator material 525 may be patterned to expose an upper surface of the inner bump 222. The patterned insulator material 525 may form the insulator 225.

In block 1640, a photoresist (PR) (740) may be deposited and patterned on the base 210, on the inner bump 222, and on the insulator 225. The PR 740 may expose an upper surface of the outer pad 247.

In block 1650, a conductive metal may be plated on the exposed upper surface of the outer pad 247 to form the outer bump 227.

In block 1660, the PR 740 may be removed.

In block 1670, a mold material 1030 may be deposited on the base 210, on the outer bump 227, on the insulator 225, and on the inner bump 222.

In block 1680, the mold material 1030 may be planarized to form the cap mold 230.

The following should be noted regarding the flows indicated in FIGS. 14 – 16. Unless otherwise indicated, the flow of blocks do not necessarily limit the ordering in which the blocks may be performed. In other words, the blocks may be performed in any order that is logical.

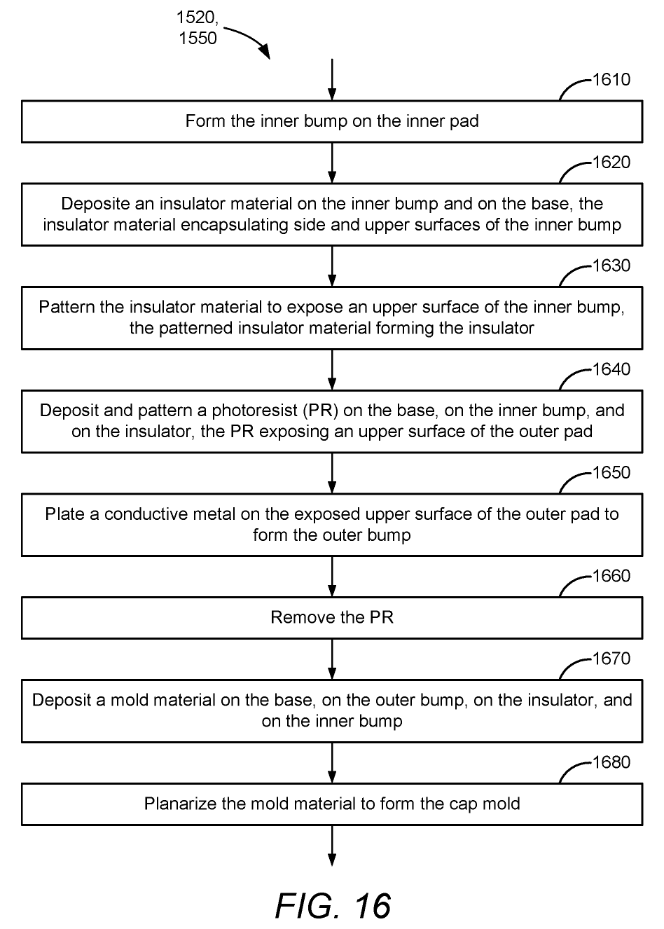

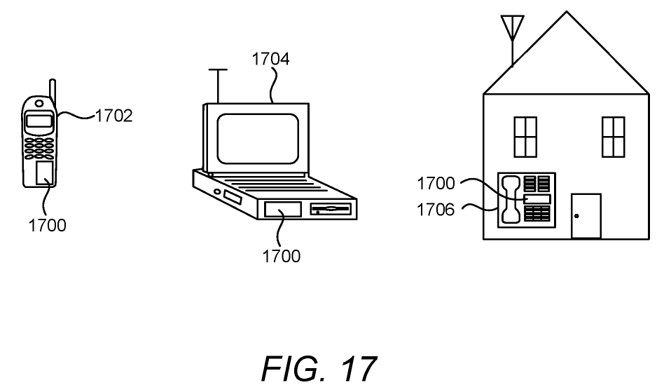

FIG. 17 illustrates various electronic devices 1700 that may be integrated with any of the aforementioned DTCs and/or semiconductor packages – such as the DTC 200 and the semiconductor package 1200 – in accordance with various aspects of the disclosure. For example, a mobile phone device 1702, a laptop computer device 1704, and a fixed location terminal device 1706 may each be considered generally user equipment (UE) and may include one or more semiconductor packages (e.g., semiconductor package 1200) as described herein. The devices 1702, 1704, 1706 illustrated in FIG. 17 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:

Clause 1: A deep trench capacitor (DTC), comprising: a base; and one or more concentric bump structures on the base, wherein at least one concentric bump structure comprises: an inner bump; an insulator surrounding the inner bump; and an outer bump surrounding the insulator, wherein the inner bump and the outer bump are conductive.

Clause 2: The DTC of clause 1, wherein the outer bump is configured to be coupled to one of power and ground, and wherein the inner bump is configured to be coupled to other of power and ground.

Clause 3: The DTC of any of clauses 1-2, wherein the base is formed from silicon (Si).

Clause 4: The DTC of any of clauses 1-3, wherein the insulator is formed from polyimide (PI).

Clause 5: The DTC of any of clauses 1-4, wherein one or both of the inner bump and the outer bump are formed conductive metals.

Clause 6: The DTC of any of clauses 1-5, wherein a diameter of the inner bump ranges between 30µm and 50µm, or wherein a thickness of the insulator ranges between 5µm and 10µm, or wherein an outer diameter of the outer bump ranges between 65µm and 95µm, or any combination thereof.

Clause 7: The DTC of any of clauses 1-6, further comprising: one or more inner pads within the base, the one or more inner pads corresponding to the one or more concentric bump structure, each inner pad in contact with a lower surface of the inner bump of the corresponding concentric bump structure; and one or more outer pads within the base, the one or more outer pads corresponding to the one or more concentric bump structure, each outer pad in contact with a lower surface of the outer bump of the corresponding concentric bump structure.

Clause 8: The DTC of any of clauses 1-7, further comprising: a cap mold on the base, wherein the cap mold encapsulates outer sides of the outer bumps of the one or more concentric bump structures.

Clause 9: The DTC of any of clauses 1-8, wherein the DTC is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

Clause 10: A method of fabricating a deep trench capacitor (DTC), the method comprising: forming a base; and forming one or more concentric bump structures on the base, wherein at least one concentric bump structure comprises: an inner bump; an insulator surrounding the inner bump; and an outer bump surrounding the insulator, wherein the inner bump and the outer bump are conductive.

Clause 11: The method of clause 10, wherein the outer bump is configured to be coupled to one of power and ground, and wherein the inner bump is configured to be coupled to other of power and ground.

Clause 12: The method of any of clauses 10-11, wherein the base is formed from silicon (Si).

Clause 13: The method of any of clauses 10-12, wherein the insulator is formed from polyimide (PI).

Clause 14: The method of any of clauses 10-13, wherein one or both of the inner bump and the outer bump are formed conductive metals.

Clause 15: The method of any of clauses 10-14, wherein a diameter of the inner bump ranges between 30µm and 50µm, or wherein a thickness of the insulator ranges between 5µm and 10µm, or wherein an outer diameter of the outer bump ranges between 65µm and 95µm, or any combination thereof.

Clause 16: The method of any of clauses 10-15, further comprising: forming one or more inner pads within the base, the one or more inner pads corresponding to the one or more concentric bump structure, each inner pad in contact with a lower surface of the inner bump of the corresponding concentric bump structure; and forming one or more outer pads within the base, the one or more outer pads corresponding to the one or more concentric bump structure, each outer pad in contact with a lower surface of the outer bump of the corresponding concentric bump structure.

Clause 17: The method of any of clauses 10-16, further comprising: forming a cap mold on the base, wherein the cap mold encapsulates outer sides of the outer bumps of the one or more concentric bump structures.

Clause 18: The method of clause 17, wherein forming the one or more concentric bump structures and forming the cap mold comprises: forming the inner bump on an inner pad; depositing an insulator material on the inner bump and on the base, the insulator material encapsulating side and upper surfaces of the inner bump; patterning the insulator material to expose an upper surface of the inner bump, the patterned insulator material forming the insulator; depositing and patterning a photoresist (PR) on the base, on the inner bump, and on the insulator, the PR exposing an upper surface of an outer pad; plating a conductive metal on the exposed upper surface of the outer pad to form the outer bump; removing the PR; depositing a mold material on the base, on the outer bump, on the insulator, and on the inner bump; and planarizing the mold material to form the cap mold.

Clause 19: A semiconductor package, comprising: a redistribution layer (RDL) comprising one or more metal layers; a die on an upper surface of the RDL; a die mold on the upper surface of the RDL, the die mold encapsulating side and upper surfaces of the die; and one or more deep trench capacitors (DTC) on a lower surface of the RDL electrically coupled to the die through the RDL, wherein at least one DTC comprises: a base; and one or more concentric bump structures on the base, wherein at least one concentric bump structure comprises: an inner bump; an insulator surrounding the inner bump; and an outer bump surrounding the insulator, and wherein the inner bump and the outer bump are conductive.

Clause 20: The semiconductor package of clause 19, further comprising: a printed circuit board (PCB) below the RDL; and a plurality interconnects in between the RDL and the PCB, wherein the PCB is electrically coupled with the die through one or more of the interconnects and the RDL, or the PCB is electrically coupled with at least one of the DTC through one or more of the interconnects and the RDL, or both.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink / reverse or downlink / forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms "connected," "coupled," or any variant thereof, mean any connection or coupling, either direct or indirect, between elements, and can encompass a presence of an intermediate element between two elements that are "connected" or "coupled" together via the intermediate element unless the connection is expressly disclosed as being directly connected.

Any reference herein to an element using a designation such as "first," "second," and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A deep trench capacitor (DTC), comprising:
a base; and
one or more concentric bump structures on the base,
wherein at least one concentric bump structure comprises:
an inner bump;
an insulator surrounding the inner bump; and
an outer bump surrounding the insulator,
wherein the inner bump and the outer bump are conductive.

2. The DTC of claim 1,
wherein the outer bump is configured to be coupled to one of power and ground, and
wherein the inner bump is configured to be coupled to other of power and ground.

3. The DTC of claim 1, wherein the base is formed from silicon (Si).

4. The DTC of claim 1, wherein the insulator is formed from polyimide (PI).

5. The DTC of claim 1, wherein one or both of the inner bump and the outer bump are formed conductive metals.

6. The DTC of claim 1,
wherein a diameter of the inner bump ranges between 30µm and 50µm, or
wherein a thickness of the insulator ranges between 5µm and 10µm, or
wherein an outer diameter of the outer bump ranges between 65µm and 95µm, or
any combination thereof.

7. The DTC of claim 1, further comprising:
one or more inner pads within the base, the one or more inner pads corresponding to the one or more concentric bump structure, each inner pad in contact with a lower surface of the inner bump of the corresponding concentric bump structure; and
one or more outer pads within the base, the one or more outer pads corresponding to the one or more concentric bump structure, each outer pad in contact with a lower surface of the outer bump of the corresponding concentric bump structure.

8. The DTC of claim 1, further comprising:
a cap mold on the base,
wherein the cap mold encapsulates outer sides of the outer bumps of the one or more concentric bump structures.

9. The DTC of claim 1, wherein the DTC is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

10. A method deep trench capacitor (DTC), comprising:
forming a base; and
forming one or more concentric bump structures on the base,
wherein at least one concentric bump structure comprises:
an inner bump;
an insulator surrounding the inner bump; and
an outer bump surrounding the insulator,
wherein the inner bump and the outer bump are conductive.

11. The method of claim 10,
wherein the outer bump is configured to be coupled to one of power and ground, and
wherein the inner bump is configured to be coupled to other of power and ground.

12. The method of claim 10, wherein the base is formed from silicon (Si).

13. The method of claim 10, wherein the insulator is formed from polyimide (PI).

14. The method of claim 10, wherein one or both of the inner bump and the outer bump are formed conductive metals.

15. The method of claim 10,
wherein a diameter of the inner bump ranges between 30µm and 50µm, or
wherein a thickness of the insulator ranges between 5µm and 10µm, or
wherein an outer diameter of the outer bump ranges between 65µm and 95µm, or
any combination thereof.

16. The method of claim 10, further comprising:
forming one or more inner pads within the base, the one or more inner pads corresponding to the one or more concentric bump structure, each inner pad in contact with a lower surface of the inner bump of the corresponding concentric bump structure; and
forming one or more outer pads within the base, the one or more outer pads corresponding to the one or more concentric bump structure, each outer pad in contact with a lower surface of the outer bump of the corresponding concentric bump structure.

17. The method of claim 10, further comprising:
forming a cap mold on the base,
wherein the cap mold encapsulates outer sides of the outer bumps of the one or more concentric bump structures.

18. The method of claim 17, wherein forming the one or more concentric bump structures and forming the cap mold comprises:
forming the inner bump on an inner pad;
depositing an insulator material on the inner bump and on the base, the insulator material encapsulating side and upper surfaces of the inner bump;
patterning the insulator material to expose an upper surface of the inner bump, the patterned insulator material forming the insulator;
depositing and patterning a photoresist (PR) on the base, on the inner bump, and on the insulator, the PR exposing an upper surface of an outer pad;
plating a conductive metal on the exposed upper surface of the outer pad to form the outer bump;
removing the PR;
depositing a mold material on the base, on the outer bump, on the insulator, and on the inner bump; and
planarizing the mold material to form the cap mold.

19. A semiconductor package, comprising:
a redistribution layer (RDL) comprising one or more metal layers;
a die on an upper surface of the RDL;
a die mold on the upper surface of the RDL, the die mold encapsulating side and upper surfaces of the die; and
one or more deep trench capacitors (DTC) on a lower surface of the RDL electrically coupled to the die through the RDL,
wherein at least one DTC comprises:
a base; and
one or more concentric bump structures on the base,
wherein at least one concentric bump structure comprises:
an inner bump;
an insulator surrounding the inner bump; and
an outer bump surrounding the insulator, and
wherein the inner bump and the outer bump are conductive.

20. The semiconductor package of claim 19, further comprising:
a printed circuit board (PCB) below the RDL; and
a plurality interconnects in between the RDL and the PCB, wherein
the PCB is electrically coupled with the die through one or more of the interconnects and the RDL, or
the PCB is electrically coupled with at least one of the DTC through one or more of the interconnects and the RDL, or
20 both.
